(19) United States
(12) Patent Application Publication
(10) Pub. No.: US 2017/0129423 A1
(43) Pub. Date: May 11, 2017

(54) SHIELDED CONDUCTIVE PATH

(71) Applicant: Sumitomo Wiring Systems, Ltd., Yokkaichi (JP)

(72) Inventor: Hidetoshi SUGINO, Yokkaichi (JP)

(21) Appl. No.: 15/347,437

(22) Filed: Nov. 9, 2016

(30) Foreign Application Priority Data
Nov. 10, 2015 (JP) 2015220125

(51) Int. Cl. B60R 16/02; H05K 9/00

(52) U.S. Cl. CPC B60R 16/0215; H05K 9/0007

(57) ABSTRACT

A shielded conductive path that can be easily manufactured. A shielded conductive path includes a tubular shielding pipe having an insertion space into which an electrical wire is insertable, and a resin pipe that is separate from the shielding pipe and is removably fitted to the outside of the shielding pipe. There is little concern that the coating of the resin pipe is peeled off when the resin pipe is bent, and thus a predetermined identification function can be exhibited.

This application claims the benefit of Japanese Application No. JP2015-220125, filed on Nov. 10, 2015, the contents of which are hereby incorporated by reference in their entirety.

### FIELD

The present invention relates to a shielded conductive path having a shield function.

### BACKGROUND

Conventionally, shielded conductive paths are known that are routed under a floor of a vehicle, such as a hybrid vehicle, and that include an electrical wire and a tubular shielding pipe into which the electrical wire is inserted. The type of shielding pipe is mainly for protecting the electrical wire and shielding noise. For example, JP 2012-165562A (Patent Document 1) discloses an electromagnetic shield tube obtained by integrally joining together an inner layer made of a resin, a metal layer, and an outer layer made of a resin.

In the above-described conventional shielded conductive path, when the electromagnetic shield tube is manufactured, relatively large equipment such as an insert molding machine or the like is required in order to integrally join the inner layer and the outer layer that are made of a resin and the metal layer, and in some cases, chemical or mechanical surface treatment needs to be performed on the metal layer, for example. Therefore, it is difficult to manufacture the electromagnetic shield tube.

The present design has been accomplished in view of the above-described circumstances, and an object of the present design is to provide a shielded conductive path that can be easily manufactured.

### SUMMARY

A shielded conductive path according to the present invention includes a tubular shielding pipe having an insertion space into which an electrical wire is insertable, and a resin pipe that is separate from the shielding pipe and is fitted to the outside of the shielding pipe.

According to the above-described configuration, when assembled, the separate resin pipe needs only to be fitted to the outside of the shielding pipe, and thus it is not necessary to integrally connect the shielding pipe and the resin pipe, and large equipment and special steps are not required. As a result, the shielded conductive path can be easily manufactured. Also, unlike with the metal pipe, there is substantially no concern that the coating of the resin pipe will be peeled off when the resin pipe is bent, and thus an identification function can be favorably exhibited by displaying a color that indicates a high voltage.

### DRAWINGS

FIG. 1 is a schematic diagram showing a path in which a shielded conductive path according to Working Example 1 is laid out;

FIG. 2 is a side view of the shielded conductive path connected to a connector of a device;

FIG. 3 is a cross-sectional view of the shielded conductive path;

FIG. 4 is a cross-sectional view of a shielding pipe;

FIG. 5 is a cross-sectional view of a resin pipe;

FIG. 6 is a cross-sectional view of a shielded conductive path according to Working Example 2;

FIG. 7 is a cross-sectional view of a shielding pipe; and

FIG. 8 is a cross-sectional view of a resin pipe.

### DESCRIPTION

A preferable embodiment will be described below.

It is preferable that a protruding portion is provided on one of the shielding pipe and the resin pipe, and a recessed portion to which the protruding portion is fitted is provided on the other of the shielding pipe and the resin pipe. The protruding portion being fitted in the recessed portion makes it possible to prevent the resin pipe from positionally shifting with respect to the shielding pipe in the circumferential direction.

It is preferable that the protruding portion is provided on the shielding pipe, and the recessed portion is provided on the resin pipe. According to this, because the protruding portion is provided using a material other than resin, the mechanical strength of the protruding portion can be ensured, preventing the protruding portion from being broken or damaged. As a result, a state in which the protruding portion and the recessed portion are fitted to each other can be favorably maintained.

The resin pipe covers a portion excluding both ends in an axial direction of the shielding pipe. According to this, the both ends in the axial direction of the shielding pipe can be exposed and a braided member can be connected to an exposed region, increasing the versatility of the shielded conductive path. In particular, in the case of the above-described conventional technique, when the shielding pipe is connected to the braided member, troublesome work such as removing an outer layer made of a resin corresponding to the both ends in the axial direction of the shielding pipe is required. However, with the above-described configuration, the resin pipe needs only to be molded smaller than the shielding pipe, and the difficulty in manufacture can be reduced.

### Working Example 1

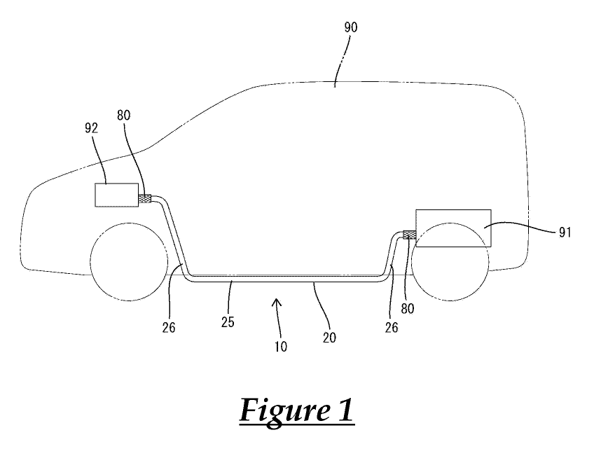

Hereinafter, Working Example 1 will be described with reference to FIGS. 1 to 5. As shown in FIG. 1, a shielded conductive path 10 according to Working Example 1 is to be routed under a floor of a vehicle body 90 in a vehicle such as a hybrid car, in order to connect a device 91 such as a high-voltage battery provided in a rear portion of the vehicle body 90 to a device 92 such as an inverter or a fuse block provided in a front portion of the vehicle body 90, for example. Note that the devices 91 and 92 are accommodated in a conductive shield case.

The shielded conductive path 10 includes a plurality (two in Working Example 1) of electrical wires 60, a shielding pipe 20, and a resin pipe 40 that is separate from the shielding pipe 20.

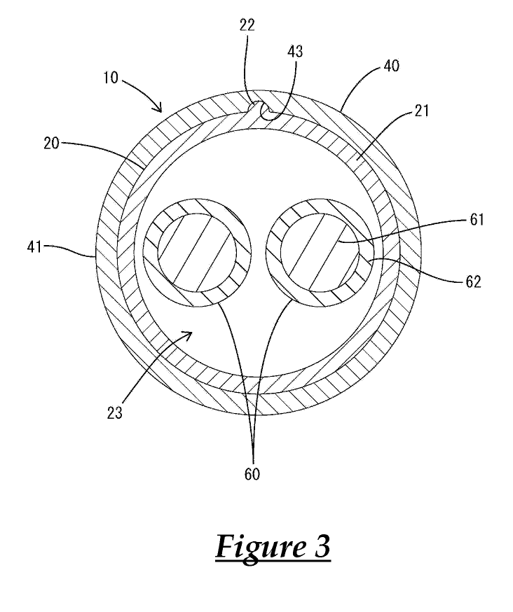

As shown in FIG. 3, the electrical wires 60 are unshielded electrical wires, each electrical wire being constituted by a conductor 61 (copper, aluminum, or the like) and a coating 62 made of an insulating resin that covers the periphery of the conductor 61. Terminal metal fittings (not shown) are connected to the ends of the electrical wires 60. The terminal metal fittings are accommodated in housings 95 and 96 of connectors 93 and 94 provided in the corresponding devices 91 and 92.

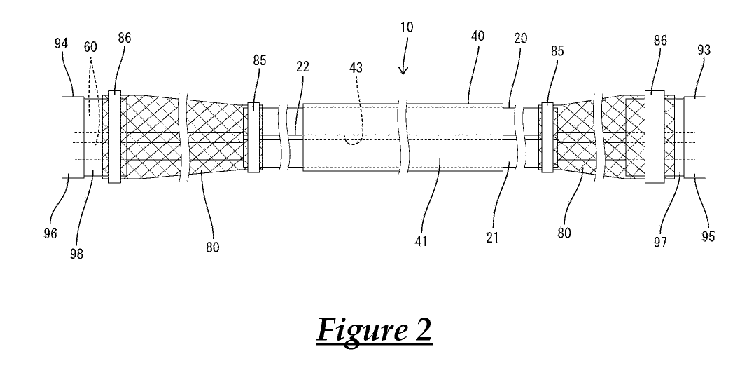

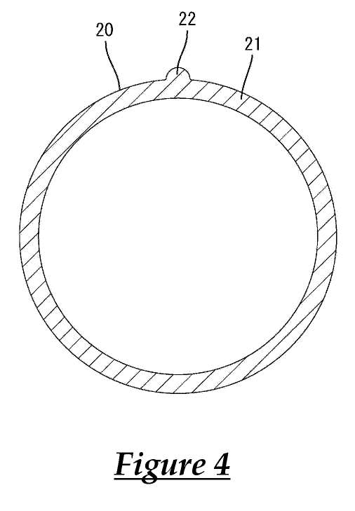

The shielding pipe 20 is made of metal (iron, aluminum, copper, stainless steel, or the like), and is formed by extrusion molding into a cross-sectional shape that is substantially uniform in the longitudinal direction (axial direction). As shown in FIGS. 2 and 4, the shielding pipe 20 is constituted by a pipe main body 21 having a tubular shape whose both ends in the longitudinal direction are open, specifically, having a cylindrical shape, and a protruding portion 22 that integrally protrudes from the outer circumferential surface of the pipe main body 21.

The pipe main body 21 has a circular cross-section, that is, has a substantially perfectly circular cross-section, and is formed to have a constant thickness over the entire circumference. As shown in FIG. 3, an inner portion of the pipe main body 21 serves as an insertion space 23 into which two electrical wires 60 are inserted together.

The protruding portion 22 has a protrudingly curved (convex) cross-section, specifically, has a semicircular cross-section, and has a protruding shape that protrudes from the pipe main body 21 over its full length. The length by which the protruding portion 22 protrudes from the pipe main body 21 is set to be smaller than the thickness of the pipe main body 21, and to be smaller than the thickness of a resin pipe 40, which will be described later.

The shielding pipe 20 is bent three-dimensionally along the path in which the electrical wires 60 are routed, and as shown in FIG. 1, the shielding pipe 20 has its lowest portion 25 routed at the lowest position in the routing path, and rising portions 26 that respectively rise from both ends of the lowest portion 25 toward the devices 91 and 92.

The resin pipe 40 is made of a synthetic resin (polypropylene, polyamide, polybutylene terephthalate, or the like), and is formed by extrusion molding into a cross-sectional shape that is substantially uniform in the longitudinal direction. In the case of Working Example 1, to indicate a high-voltage circuit, an orange resin is extruded to produce the resin pipe 40, and the entire resin pipe 40 is colored with an identification display portion 41, which may be orange, for example. As shown in FIG. 2, the resin pipe 40 is removably fitted to the outside of the shielding pipe 20, and the full length of the resin pipe 40 is shorter than the full length of the shielding pipe 20.

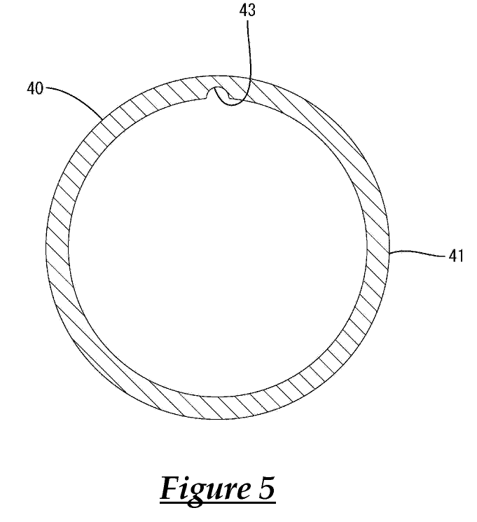

Specifically, the resin pipe 40 has a circular cross-section, that is, has a substantially perfectly circular cross-section, and has a cylindrical shape whose both ends in the longitudinal direction are open. As shown in FIG. 5, a recessed portion 43 is provided on the inner circumferential surface of the resin pipe 40, and except for a portion corresponding to the recessed portion 43, the resin pipe 40 is provided with a constant thickness in the circumferential direction. The thickness of the resin pipe 40 (except for the portion corresponding to the recessed portion 43) may be larger than the thickness of the pipe main body 21. Also, the inner diameter of the resin pipe 40 (except for the portion corresponding to the recessed portion 43) is substantially the same as the outer diameter (except for the portion corresponding to the protruding portion 22) of the pipe main body 21 of the shielding pipe 20, or is slightly smaller than the outer diameter of the pipe main body 21.

The recessed portion 43 has a recedingly curved (concave) cross-section, specifically, a U-shaped cross-section, and has a groove shape such that the recessed portion 43 extends over the full length of the resin pipe 40 and both its ends are open in the longitudinal direction. The recessed portion 43 has a shape corresponding to the shape of the protruding portion 22, and as shown in FIG. 3, the protruding portion 22 is tightly fitted to the inside of the recessed portion 43. The depth of the recessed portion 43 is substantially the same as the length by which the protruding portion 22 protrudes, or is slightly smaller than the length by which the protruding portion 22 protrudes, and is set to half the thickness of the resin pipe 40 (except for the portion corresponding to the recessed portion 43).

As shown in FIG. 2, portions of the electrical wires 60 that are led out from both ends in the longitudinal direction of the shielding pipe 20 to the outside are collectively surrounded by the braided member 80. The braided member 80 is obtained by weaving a conductive thin metal wire (copper or the like) into a mesh and forming the woven metal wire into tubular shape. Note that metal foil may be wrapped instead of the braided member 80.

One end in the longitudinal direction of the braided member 80 is conductively fixed to the outer circumferential surface of an end of the shielding pipe 20 by that one end being crimped by an annular metal band 85. Also, the other end in the longitudinal direction of the braided member 80 is conductively fixed to shield shells 97 and 98 of the connectors 93 and 94 of the devices 91 and 92.

Next, an example of a method for manufacturing the shielded conductive path 10 according to Working Example 1 will be described.

After the shielding pipe 20 and the resin pipe 40 are individually extruded with an existing extrusion machine, the resin pipe 40 is cut to be shorter than the shielding pipe 20. Accordingly, the shielding pipe 20 and the resin pipe 40 are individually formed.

Subsequently, the resin pipe 40 is assembled to the shielding pipe 20. For assembly, the shielding pipe 20 is inserted from the opening of the end of the resin pipe 40 into the resin pipe 40. In the assembly process, the inner circumferential surface of the resin pipe 40 and the outer circumferential surface of the shielding pipe 20 slide against each other, and are positioned in the circumferential direction due to the protruding portion 22 being fitted to the recessed portion 43. Upon completion of assembly, the resin pipe 40 is fitted to the outside of the portion excluding both ends in the longitudinal direction of the shielding pipe 20, and both ends in the longitudinal direction of the shielding pipe 20 are exposed. At this time, the resin pipe 40 is kept in a state in which the movement of the resin pipe 40 in the longitudinal direction is restricted by the shielding pipe 20 due to a frictional resistance between its inner circumferential surface and the outer circumferential surface of the shielding pipe 20. Also, the resin pipe 40 is kept in a state in which a rotation relative to the shielding pipe 20 about its axis is restricted by the protruding portion 22 being fitted to the recessed portion 43.

Subsequently, two electrical wires 60 are inserted into the insertion space 23 of the shielding pipe 20, the electrical wires 60 that are led out from both ends in the longitudinal direction of the shielding pipe 20 are connected to the corresponding connectors 93 and 94 of the devices 91 and 92. Next, the regions exposed at both ends in the longitudinal direction of the shielding pipe 20 are each covered with one end in the longitudinal direction of the braided member 80 and are each crimped with the metal band 85. The shield shells 97 and 98 of the connectors 93 and 94 of the corresponding devices 91 and 92 are each covered with the other end in the longitudinal direction of the braided member 80, and are each crimped with a metal band 86. Accordingly, the two electrical wires 60 are shielded by the braided member 80 and the shield shells 97 and 98 in full length, resulting in a state in which noise leakage is prevented.

Next, the shielding pipe 20 and the resin pipe 40 are bent into a predetermined shape with a pipe bender.

In portions where the shielding pipe 20 and the resin pipe 40 are both bent, positional shifts with respect to the shielding pipe 20 in the longitudinal direction of the resin pipe 40 are restricted. Here, because positional shifts with respect to the shielding pipe 20 in the circumferential direction of the resin pipe 40 are restricted by engagement between the recessed portion 43 and the protruding portion 22, the resin pipe 40 is kept in a state in which the resin pipe 40 is positioned with respect to the shielding pipe 20 in the circumferential direction and the longitudinal direction. Note that the resin pipe 40 has at least a thickness to an extent that the resin layer is not torn at the time of bending. Thus, the identification display portion 41 on the outer surface of the resin pipe 40 is displayed without being damaged, and the reliability of an identification function that is indicative of high voltage is ensured.

Next, the functional effect and effect of Working Example 1 will be described.

The shielded conductive path 10 according to Working Example 1 includes a tubular shielding pipe 20 having an insertion space 23 into which electrical wires 60 are inserted, and a resin pipe 40 that is separate from the shielding pipe 20 and is fitted to the outside of the shielding pipe 20.

According to the above-described configuration, for assembly, the resin pipe 40 needs only to be fitted to the outside of the shielding pipe 20. Therefore, it is not necessary to integrally connect the shielding pipe 20 and the resin pipe 40 to each other, large equipment such as an insert molding machine and special steps are not required. As a result, the shielded conductive path 10 can be easily manufactured. Moreover, unlike with a metal pipe, there is substantially no concern that coating of the resin pipe 40 is peeled off at the time of bending, making it possible to favorably display the identification display portion 41 indicating high voltage.

Also, since the protruding portion 22 is provided on the shielding pipe 20 and the recessed portion 43 to which the protruding portion 22 is fitted is provided on the resin pipe 40, positional shifts of the resin pipe 40 with respect to the shielding pipe 20 in the circumferential direction are restricted due to the protruding portion 22 and the recessed portion 43 being fitted to each other. In particular, since the protruding portion 22 is provided on the shielding pipe 20 and not provided on the resin pipe 40, which is made of a resin, the mechanical strength of the protruding portion 22 can be ensured and it is possible to prevent the protruding portion 22 from being broken or damaged. As a result, a state in which the protruding portion 22 and the recessed portion 43 are fitted to each other can be favorably maintained.

Moreover, since the resin pipe 40 covers the portion excluding both ends in the longitudinal direction of the shielding pipe 20, the braided members 80 can be connected to the exposed regions on both ends in the longitudinal direction of the shielding pipe 20. In this case, the resin pipe 40 needs only to be made shorter than the shielding pipe 20, and thus the difficulty in manufacture can be further reduced.

### Working Example 2

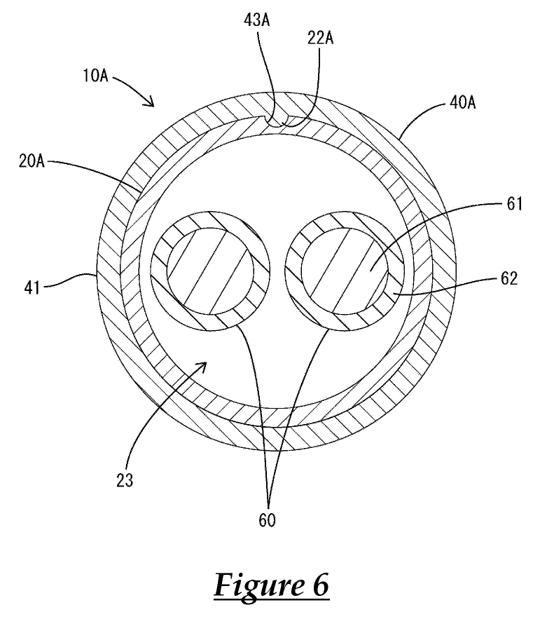

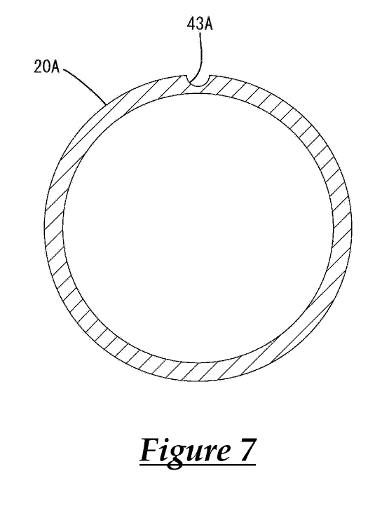

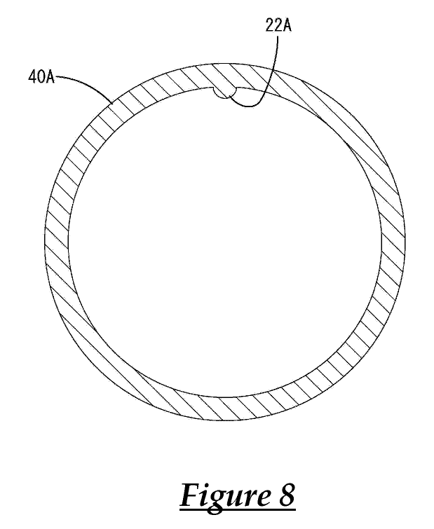

Working Example 2 is shown in FIGS. 6 to 8. In contrast to Working Example 1, in a shielded conductive path 10A according to Working Example 2, a recessed portion 43A is provided on the outer circumferential surface of a shielding pipe 20A, and a protruding portion 22A is provided on an inner circumferential surface of a resin pipe 40A. In other words, although the recessed portion 43A is open inwardly and the protruding portion 22A protrudes outwardly in Working Example 1, in the case of Working Example 2, the recessed portion 43A is open outwardly and the protruding portion 22A protrudes inwardly.

The recessed portion 43A and the protruding portion 22A have shapes such that they can be fitted to each other, and have similar shapes to Working Example 1. When the resin pipe 40A is assembled to the shielding pipe 20A, the protruding portion 22A of the resin pipe 40A is fitted to the recessed portion 43A of the shielding pipe 20A, and the resin pipe 40A is kept in a state in which the resin pipe 40A is positioned by the shielding pipe 20A in the circumferential direction. This aspect is similar to Working Example 1. In the case of Working Example 2, since the recessed portion 43A is provided on the shielding pipe 20A made of a metal, even if the depth of the recessed portion 43A increases, the mechanical strength of the shielding pipe 20A does not excessively decrease.

### Other Working Example

Hereinafter, other working examples will be described simply.

Molding is not limited to extrusion molding, and the shielding pipe and the resin pipe can also be manufactured by other known molding means such as press molding, for example. For example, the shielding pipe may be manufactured by casting.

The protruding portion and the recessed portion may be provided in only a portion, e.g. an end or a middle portion in the longitudinal direction of each pipe (the shielding pipe or the resin pipe), or may be provided at a plurality of positions in the longitudinal direction of each pipe at an interval. Furthermore, the protruding portion and the recessed portion may be provided at a plurality of positions in the circumferential direction of each pipe at an interval.

It is sufficient that the protruding portion and the recessed portion have a structure such that positional shifts in the circumferential direction of the resin pipe with respect to the shielding pipe can be restricted, the protruding portion and the recessed portion do not need to be tightly fitted to each other, and need only to have a structure such that they can abut against each other in the circumferential direction.

The protruding portion and the recessed portion may have a square cross-section.

The shielding pipe may have an elliptical, oblong, square cross-section, or the like.

The thickness of the resin pipe may be smaller than the thickness of the shielding pipe.

It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example,” “e.g.,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

1. A shielded conductive path, comprising:
a tubular shielding pipe having an insertion space into which an electrical wire is insertable; and
a resin pipe that is separate from the shielding pipe and is fitted to the outside of the shielding pipe.

2. The shielded conductive path according to claim 1, wherein
a protruding portion is provided on one of the shielding pipe and the resin pipe, and a recessed portion to which the protruding portion is fitted is provided on the other of the shielding pipe and the resin pipe.

3. The shielded conductive path according to claim 2, wherein
the protruding portion is provided on the shielding pipe, and the recessed portion is provided on the resin pipe.

4. The shielded conductive path according to claim 1, wherein
the resin pipe covers a portion excluding both ends in an axial direction of the shielding pipe.

5. The shielded conductive path according to claim 2, wherein
the resin pipe covers a portion excluding both ends in an axial direction of the shielding pipe.

6. The shielded conductive path according to claim 3, wherein
the resin pipe covers a portion excluding both ends in an axial direction of the shielding pipe.
